(19) United States
(12) Patent Application Publication
(10) Pub. No.: US 2012/0142189 A1
(43) Pub. Date: Jun. 7, 2012

(54) METHOD FOR FABRICATING SEMICONDUCTOR DEVICE

(76) Inventor: Sung-Kwon LEE, Gyeonggi-do (KR)

(21) Appl. No.: 13/237,401

(22) Filed: Sep. 20, 2011

(30) Foreign Application Priority Data
Dec. 7, 2010 (KR) 10-2010-0123961

(51) Int. Cl. H01L 21/768

(52) U.S. Cl. 438/675; 257/E21.577

(57) ABSTRACT

A method for fabricating a semiconductor device includes sequentially forming an etch stop layer and a mold layer over a substrate, forming an open region by selectively etching the mold layer until the etch stop layer is exposed, transforming a surface of the mold layer into an insulation layer by performing a surface treatment, and forming a conductive layer inside the open region.

### CROSS-REFERENCE TO RELATED APPLICATIONS

The present application claims priority of Korean Patent Application No. 10-2010-0123961, filed on Dec. 7, 2010, which is incorporated herein by reference in its entirety.

### BACKGROUND

1. Field of the Invention

Exemplary embodiments of the present invention relate to a semiconductor device fabrication technology, and more particularly, to a method for forming an open region having a high aspect ratio such as a storage node hole of a semiconductor device.

2. Description of the Related Art

As semiconductor devices become more and more integrated, the aspect ratio of a storage node hole is increasing to secure sufficient capacitance within a limited area.

FIGS. 1A and 1B are cross-sectional views illustrating a typical method for forming a storage node hole.

Referring to FIG. 1A, an inter-layer dielectric layer 12 is formed over a substrate 11 in which a predetermined structure may be already formed, and then storage node contact plugs 13 penetrating the inter-layer dielectric layer 12 are formed. Subsequently, an etch stop layer 14, a mold layer 15, and a hard mask pattern 16 are sequentially disposed over the inter-layer dielectric layer 12. Herein, the mold layer 15 may be an insulation layer, e.g., an oxide layer.

Referring to FIG. 1B, storage node holes 17 exposing the storage node contact plugs 13 are formed by using the hard mask pattern 16 as an etch barrier and etching the mold layer 15 and the etch stop layer 14. Subsequently, although not illustrated in the drawing, storage nodes are formed in the inside of the storage node holes 17.

According to the conventional technology, however, as the linewidth (or diameter) of a storage node hole 17 decreases, etch characteristics may deteriorate as it goes toward the lower region of the storage node hole 17 and thus sufficient bottom critical dimension CD may not be secured. In the worst case, a not-open situation may occur. If the over-etch time is increased in order to avoid this situation, a bowing B phenomenon may occur in the upper portion of the storage node hole 17. Since the not-open situation and the bowing B phenomenon may be in a trade-off relationship, it is desirable to develop a method for reducing both not-open situations and the bowing B phenomenon at the same time.

### SUMMARY

Exemplary embodiments of the present invention are directed to a semiconductor device fabrication method which is capable of reducing a not-open situation and a bowing phenomenon during a process for forming an open region having a high aspect ratio, such as a storage node hole.

In accordance with an exemplary embodiment of the present invention, a method for fabricating a semiconductor device includes sequentially forming an etch stop layer and a mold layer over a substrate, forming an open region by selectively etching the mold layer until the etch stop layer is exposed, transforming a surface of the mold layer into an insulation layer by performing a surface treatment, and forming a conductive layer inside the open region.

In accordance with another exemplary embodiment of the present invention, a method for fabricating a semiconductor device includes sequentially forming an etch stop layer and a silicon layer over a substrate in which a storage node contact plug is formed, forming an open region by selectively etching the silicon layer until the etch stop layer is exposed, transforming a surface of the silicon layer into a silicon insulation layer by performing a surface treatment, etching the etch stop layer under the open region to expose the storage node contact plug, and forming a storage node inside the open region.

### BRIEF DESCRIPTION OF THE DRAWINGS

FIGS. 1A and 1B are cross-sectional views illustrating a typical method for forming a storage node hole.

FIGS. 2A to 2E are cross-sectional views illustrating a method for fabricating a semiconductor device in accordance with an exemplary embodiment of the present invention.

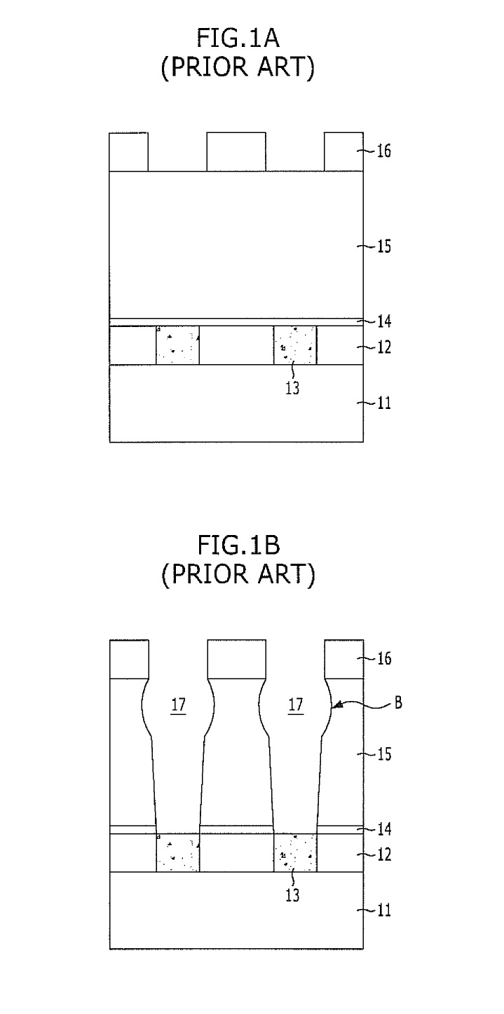

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it may not only refer to a case where the first layer is formed directly on the second layer or the substrate, but may also refer to a case where a third layer exists between the first layer and the second layer or the substrate.

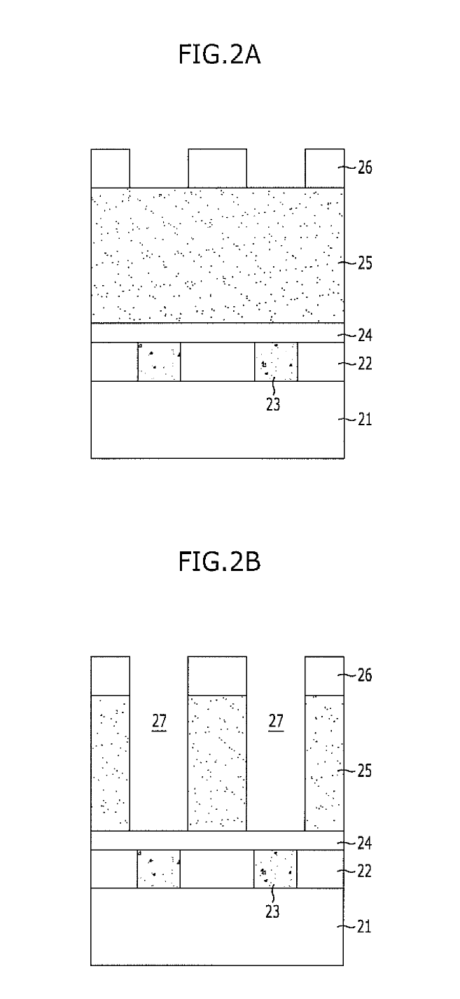

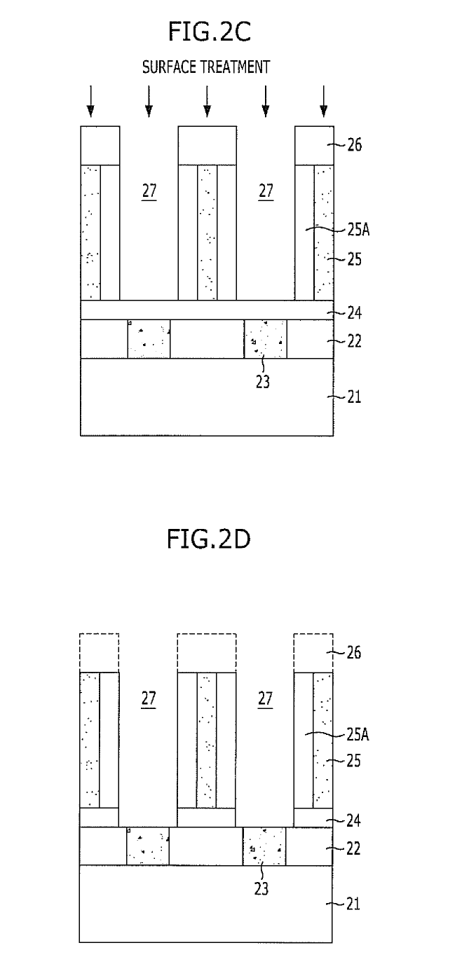

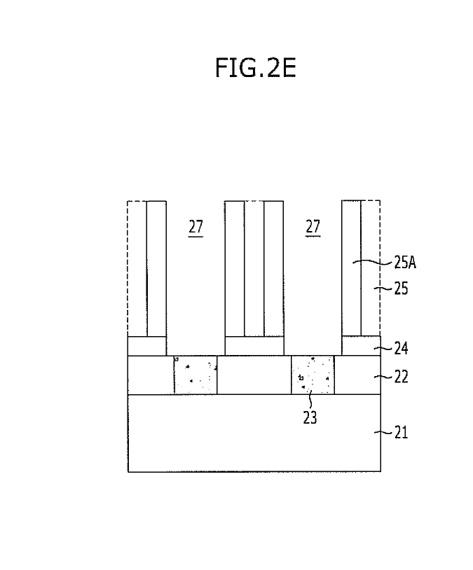

FIGS. 2A to 2E are cross-sectional views illustrating a method for fabricating a semiconductor device in accordance with an exemplary embodiment of the present invention.

Referring to FIG. 2A, an inter-layer dielectric layer 22 is formed over a substrate 21 in which structures such as transistors, word lines, bit lines, etc. may already be disposed. Herein, the inter-layer dielectric layer 22 may be any single layer selected from the group consisting of an oxide layer, a nitride layer, and an oxynitride layer, or a stacked structure thereof.

Subsequently, a plurality of storage node contact plugs 23, penetrating the inter-layer dielectric layer 22, are formed. The storage node contact plugs 23 may be a metallic layer, such as tungsten (W), titanium (Ti), and titanium nitride (TiN), or a silicon layer, or the storage node contact plugs 23 may be formed as a stacked layer in which a metallic layer and a silicon layer are stacked.

Subsequently, an etch stop layer 24 is formed over the inter-layer dielectric layer 22 in which the storage node contact plugs 23 are formed, The etch stop layer 24 may be a nitride layer.

Subsequently, a mold layer 25 is formed over the etch stop layer 24. The mold layer 25 may be transformed into an insulation layer through a subsequent process, and it may be formed of a material having an etch selectivity with respect to the nitride layer obtained from the transformation. For example, the mold layer 25 may be formed of a silicon layer, and the silicon layer may be a polysilicon layer.

Herein, since a desirable thickness of the mold layer 25, which is required by a typical semiconductor device, cannot be obtained by using a single insulation layer according to conventional technology, a method of stacking a plurality of insulation layers has been used. However, according to the exemplary embodiment of the present invention, the mold layer 25 is formed by using a silicon layer and may be preferably formed to have a desirable thickness required by a semiconductor device by using a single layer. Moreover, since a polysilicon layer may be deposited at a faster speed than an insulation layer at a low temperature, the thermal stability and productivity of the mold layer 25 may be improved.

Subsequently, a hard mask pattern 26 is formed over the mold layer 25.

Referring to FIG. 2B, the mold layer 25 is etched until the etch stop layer 24 over the storage node contact plugs 23 is exposed by using the hard mask pattern 26 as an etch barrier. As a result, open regions 27, e.g., storage node holes, are formed. Herein, the etch process for forming the open regions 27 is performed by a chemical etch method. For example, the etch process for forming the open regions 27 may be performed using a mixed gas of hydrogen bromide (HBr) gas and chlorine (Cl₂) gas that may remove the silicon layer through a chemical reaction.

Herein, when the mold layer 25 is formed by using an insulation layer, a physical etch process is typically performed during the formation of the open regions 27. This is because it is difficult and takes a long time to etch an insulation layer through a chemical reaction. When the open regions 27 are formed through a physical process, the sidewalls of each open region 27 may be slanted, thereby causing a not-open situation or a bowing phenomenon due to the etch characteristics of the physical process. On the other hand, when the mold layer 25 is formed by using a silicon layer that may be easily etched through a chemical reaction, the bowing phenomenon may be prevented or reduced. Therefore, since an over-etch process may be performed for a sufficient amount of time, the not-open situation may be prevented.

Referring to FIG. 2C, a surface treatment is performed to transform the surface of the mold layer 25 exposed by the open regions 27, which are storage node holes, into an insulation layer 25A. Herein, during the surface treatment, the etch stop layer 24 under the open regions 27 protects the storage node contact plugs 23 from being damaged.

The surface treatment may be performed by using any one selected from the group consisting of oxidation, nitration, and oxynitrocarburising. Each of the oxidation, nitration, and oxynitrocarburising may be performed through a method selected from the group consisting of thermal treatment, plasma treatment, and radical treatment, or through more than two methods performed simultaneously. For example, the surface treatment may be performed by implementing any one of thermal treatment, plasma treatment, and radical treatment, or it may be performed by implementing thermal treatment and plasma treatment at the same time.

When the mold layer 25 is formed as a silicon layer, the insulation layer 25A may be any one selected from the group consisting of a silicon oxide layer, a silicon nitride layer, and a silicon oxynitride layer. Herein, the insulation layer 25A is formed through the surface treatment to have a uniform thickness, which is advantageous. This is because a reactant for the surface treatment is uniformly applied to the surface of the substrate structure including the open regions 27 in the state of gas, ion, or radical.

Referring to FIG. 2D, the storage node contact plugs 23 are exposed by etching the etch stop layer 24 under the open regions 27 by using the hard mask pattern 26 as an etch barrier.

Subsequently, the hard mask pattern 26 is removed.

In this case, when storage nodes are formed after the above-described process, the storage nodes may be concave storage nodes. Herein, although the mold layer 25 is formed of a conductive material such as silicon, the mold layer 25 is electrically isolated from the storage nodes by the etch stop layer 24 and the insulation layer 25A. That is, the insulation layer 25A and the etch stop layer 24 may be formed to have substantial thicknesses in order to electrically isolate the mold layer 25 from the storage nodes.

Referring to FIG. 2E, the remaining mold layer 25 is removed. The remaining mold layer 25 may be removed through a dry etch process or a wet etch process. When the mold layer 25 is removed through a dry etch process, a mixed gas of hydrogen bromide (HBr) gas and chlorine (Cl₂) gas may be used. When the mold layer 25 is removed through a wet etch process, a nitric acid (HNO₃) may be used.

Subsequently, cylindrical storage nodes are formed in the inside of the open regions 27, which are not illustrated in the drawing.

As described above, both the not-open situation and the bowing phenomenon may be simultaneously prevented in the open regions 27 having a high aspect ratio by forming the mold layer 25 of a material that may be transformed into the insulation layer 25A through a surface treatment.

Although the technology of the present invention is described by exemplifying a method for forming a storage node hole, the technological scope of the present invention may be generally applied to a method for forming an open region having a high aspect ratio. For example, the technological concept and scope of the present invention may also be implemented in a process for forming plugs for metal contacts having a high aspect ratio, e.g., M1C.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
sequentially forming an etch stop layer and a mold layer over a substrate;
forming an open region by selectively etching the mold layer until the etch stop layer is exposed;
transforming a surface of the mold layer into an insulation layer by performing a surface treatment; and
forming a conductive layer inside the open region.

2. The method of claim 1, further comprising:
removing a remaining portion of the mold layer, before the forming of the conductive layer inside the open region.

3. The method of claim 1, wherein the forming of the open region is performed through a chemical etch process.

4. The method of claim 1, wherein the surface treatment is performed using one selected from the group consisting of oxidation, nitration, and oxynitrocarburising.

5. The method of claim 4, wherein the surface treatment is performed using one selected from the group consisting of thermal treatment, plasma treatment, radical treatment, and a combination thereof.

6. The method of claim 1, wherein the mold layer is formed of a material having an etch selectivity with respect to the insulation layer transformed from the mold layer.

7. The method of claim 1, wherein the forming of the conductive layer comprises etching the etch stop layer under the open region.

8. The method of claim 7, wherein the conductive layer comprises storage nodes and contact plugs.

9. The method of claim 1, wherein the mold layer comprises a silicon layer.

10. The method of claim 1, wherein the insulation layer comprises one selected from the group consisting of a silicon oxide layer, a silicon nitride layer, and a silicon oxynitride layer.

11. A method for fabricating a semiconductor device, comprising:
sequentially forming an etch stop layer and a silicon layer over a substrate in which a storage node contact plug is formed;
forming an open region by selectively etching the silicon layer until the etch stop layer is exposed;
transforming a surface of the silicon layer into a silicon insulation layer by performing a surface treatment;
etching the etch stop layer under the open region to expose the storage node contact plug; and
forming a storage node inside the open region.

12. The method of claim 11, further comprising:
removing a remaining portion of the silicon layer, before the forming of the storage node inside the open region.

13. The method of claim 11, wherein the forming of the open region is performed through a chemical etch process.

14. The method of claim 11, wherein the surface treatment is performed using one selected from the group consisting of oxidation, nitration, and oxynitrocarburising.

15. The method of claim 14, wherein the surface treatment is performed using one selected from the group consisting of thermal treatment, plasma treatment, radical treatment, and a combination thereof.

16. The method of claim 11, wherein the silicon layer comprises a polysilicon layer.

17. The method of claim 11, wherein the silicon insulation layer comprises one selected from the group consisting of a silicon oxide layer, a silicon nitride layer, and a silicon oxynitride layer.

18. The method of claim 11, wherein the silicon insulation layer and the etch stop layer have substantial thicknesses which electrically isolate the silicon layer from the storage node.
